(19) United States
(12) Patent Application Publication
(10) Pub. No.: US 2004/0020439 A1
(43) Pub. Date: Feb. 5, 2004

(54) Process chamber window assembly

(76) Inventors: Chin-Jen Chen, Tien Wei Hsiang (TW); Ming-Yuan Chen, Ping Tung City (TW); Shui-Yen Lu, Shu-Lin Hsiang (TW); Te-Keo Liu, Kwang Hsi Town (TW)

Correspondence Address: HARNESS, DICKEY & PIERCE, P.L.C., P.O. BOX 828, BLOOMFIELD HILLS, MI, 48303, US

(21) Appl. No.: 10/208,333

(22) Filed: Jul. 30, 2002

(51) Int. Cl. C23C 16/00; H01L 21/306

(52) U.S. Cl. 118/733; 156/345.1

(57) ABSTRACT

A process chamber window assembly is described. The process chamber window has an opening in a chamber body, a quartz window plane located on the opening and sealed with a O-ring and a buffer pad with an opening having the same shape as the quartz window pane located thereon. The window also has a view port located in the buffer pad and a fixed frame located on the view port. Screws through a plurality of screw holes in the fixed frame, the view port, the buffer pad and the chamber body fasten the window assembly to the chamber body.

### BACKGROUND OF THE INVENTION

1. Field of Invention

The present invention relates to a process chamber window. More particularly, the present invention relates to a process chamber window assembly for plasma process equipment.

2. Description of Related Art

Plasma processes for fabricating semiconductor devices have been extensively developed. Plasma-assisted depositions can reduce the thermal budget in a fabrication process, and plasma etching can provide anisotropic etching. AC plasma, reacted by radio frequency power, is often used in most processes.

It is difficult to check whether the plasma is reacted or not. Therefore, the process chamber must provide a window for monitoring the plasma. As a result, a visual check via the process window can be performed to monitor the processes. FIG. 1 illustrates an exploded view of a conventional plasma process chamber window. A frame 101, which is bonded to a chamber body 100, has a window opening 102. A portion of the chamber body 100 around the window opening 102 has several screw holes 104. An O-ring 106 is located between the window opening 102 and several screw holes 104, and a quartz window 108 is located upon the O-ring 106. A view port 114, made from metal material such as grille, is located upon the quartz window 108 for shielding from the RF power emission. A fixed frame 116 is located upon the view port 114.

There is a plurality of screw holes 118 in the view port 114 and the fixed frame 116 corresponding with screw holes 104 in the chamber body 100. The O-ring, the quartz window 108, the view port 114 and the fixed frame 116 are fastened by screws 120 through screw holes 104 and screw holes 118.

The view port 114 is essential component of the window assembly for the purpose of protecting the viewer. However, the window assembly needs to be fastened by screws to avoid leakage. The quartz window 108 pressed by the view port 114 may crack because of irregular stress caused by pressure and temperature. In regular industrial use, the quartz window 108 cracks and needs to be replaced in the weekly preventive maintenance. The high replacement rate of the quartz window 108 increases the cost of the manufacturing process.

### SUMMARY OF THE INVENTION

It is therefore an objective of the present invention to provide an improved window assembly, which is applied to plasma process chamber, to avoid cracking the quartz window by irregular stress caused by pressure and temperature.

In accordance with the foregoing and other objectives of the present invention, a buffer pad is added between the quartz window and the view port as a pressure buffer to avoid cracking of the quartz window. According to the demands, the buffer pad should be cost-effective, easily processed, deformity-proof (not deformity inclined) and have the capability to resist irregular stress caused by pressure and temperature. The buffer pad can be made of silicone. The buffer pad serves as a buffer interface, between the quartz window and the metal material such as a view port, to avoid cracking of the quartz window.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates the exploded view of a conventional plasma process chamber window; and

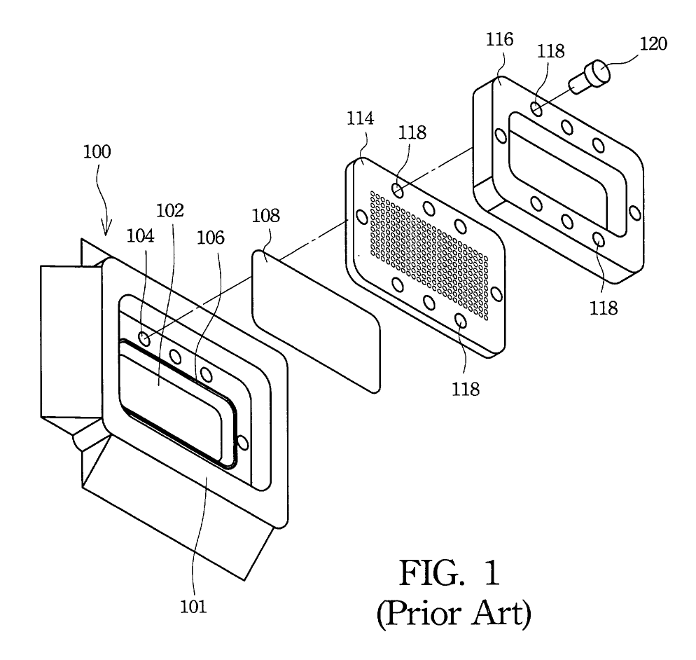

FIG. 2 illustrates the exploded view of a plasma process chamber window according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

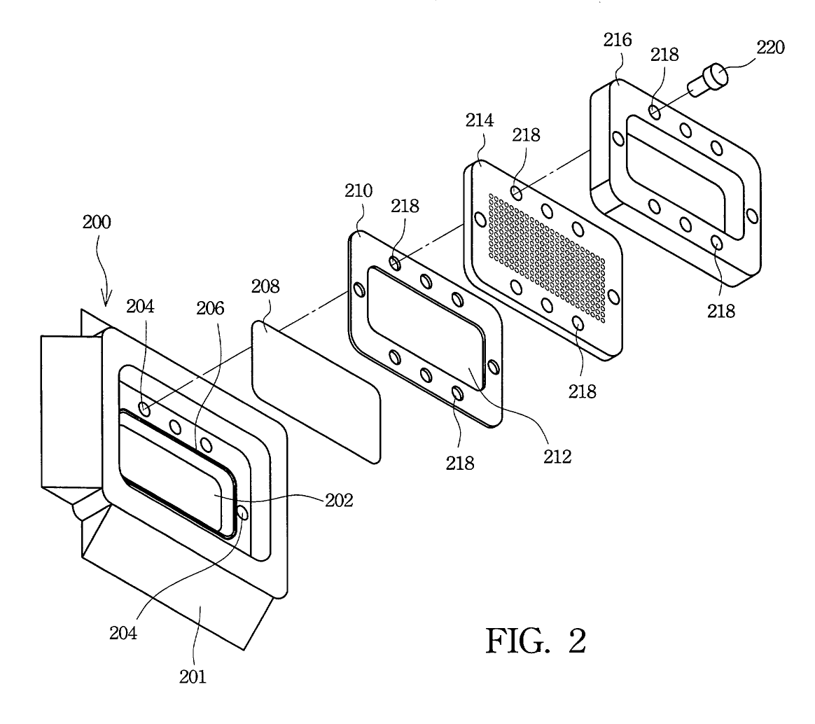

FIG. 2 illustrates an exploded view of a plasma process chamber window according to one preferred embodiment of this invention.

As shown in FIG. 2, a frame 201, which is bonded to a chamber body 200, has a window opening 202. A portion of chamber body 200 around the window opening 202 has several screw holes 204 therein.

An O-ring 206 is located between the window opening 202 and the screw holes 204, and a quartz window 208 is located upon the O-ring 206. A buffer pad 210 is located upon the quartz window 208. The buffer pad 210 has an opening 212 with a shape identical to that of the quartz window 208, and the area of the opening 212 is less than that of the quartz window 208.

A view port 214 is located upon the buffer pad 210 for shielding from the RF power emission. A fixed frame 216 is located upon the view port 214.

There is a plurality of screw holes 218 in the buffer pad 210, the view port 214 and the fixed frame 216. Screw holes 218 correspond to screw holes 204 in the chamber body 200. The O-ring 206, the quartz window 208, the buffer pad 210, the view port 214 and the fixed frame 216 are fastened to the chamber body 200 by screws 220 through screw holes 204 and screw holes 218.

According to the preferred embodiment of this invention, the quartz window 208 can be protected from the press of the view port 214 and the fixed frame 216. The material of buffer pad 210 should be heatproof, easily processed and deformity-proof.

According to the buffer pad structure placed between the quartz window and the view port, the quartz window can be protected from the pressure of the view port to avoid cracking. The material of buffer pad should be cost-effective, easily processed, deformity-proof (not deformity inclined), heatproof and have the capability to resist irregular stress caused by pressure and temperature. The buffer pad serves as a buffer interface, between the quartz window and a metal material such as a view port, to avoid cracking of the quartz window.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A process chamber window assembly, comprising:
a window opening of a chamber body;
an O-ring, located upon a portion of said chamber body around said window opening;
a quartz window, located upon said O-ring;
a buffer pad, located upon said quartz window, said buffer pad having an opening, wherein a shape of the opening and that of said quartz window are identical, and an area of said opening is less than that of said quartz window;
a view port, located upon said buffer pad; and
a fixed frame, located upon said view port, wherein said chamber body, said buffer pad, said view port, and said fixed frame all have a plurality of corresponding screw holes, and said chamber body, said buffer pad, said view port, and said fixed frame are fastened to said chamber body by a plurality of screws through said plurality of corresponding screw holes.

2. The process chamber window assembly as claimed in claim 1, wherein said buffer pad is made from a deformity-proof, heatproof and easily processed material.

3. The process chamber window assembly as claimed in claim 2, wherein said buffer pad is made from silicone.

4. A quartz window protecting apparatus, a quartz window being applied to a plasma process chamber window, said quartz window protecting apparatus at least comprising:
a buffer pad, located upon said quartz window, wherein said buffer pad is fastened to said plasma process chamber window by a plurality of screws through a plurality of screw holes therein.

5. The quartz window protecting apparatus as claimed in claim 4, wherein said window assembly apparatus under said quartz window further comprises:
a window opening of a chamber body; and
an O-ring, located upon a portion of said chamber body around said window opening.

6. The quartz window protecting apparatus as claimed in claim 4, wherein said window assembly apparatus above said quartz window further comprises:
a view port, located upon said buffer pad; and
a fixed frame, located upon said view port.

7. The quartz window protecting apparatus as claimed in claim 4, wherein said buffer pad is made from a deformity-proof, easily processed and heatproof material.

8. The quartz window protecting apparatus as claimed in claim 4, wherein said buffer pad is made from silicone.

9. The quartz window protecting apparatus as claimed in claim 4, wherein said buffer pad has a opening, the opening and said quartz window are identical in shape, and an area of said opening is less than that of said quartz window;
